(19) United States
(12) Patent Application Publication
(10) Pub. No.: US 2013/0344629 A1
(43) Pub. Date: Dec. 26, 2013

(54) IMPROVED SYSTEM FOR SUBSTRATE PROCESSING

(71) Applicants: Seung Ho Baek, Singapore (SG); Jong Jae Jung, Singapore (SG); Tae Jin Kim, Singapore (SG)

(72) Inventors: Seung Ho Baek, Singapore (SG); Jong Jae Jung, Singapore (SG); Tae Jin Kim, Singapore (SG)

(73) Assignee: ROKKO SYSTEMS PTE LTD, Singapore (SG)

(21) Appl. No.: 14/002,861

(22) PCT Filed: Mar. 2, 2012
(86) PCT No.: PCT/SG2012/000066

§ 371 Date: Sep. 3, 2013

(30) Foreign Application Priority Data
Mar. 2, 2011 (SG) 201101556-7

(51) Int. Cl. H01L 21/67; H01L 21/677

(52) U.S. Cl. CPC H01L 21/67288; H01L 21/67703; H01L 21/67
USPC 438/16; 356/364; 29/25.01; 83/559; 34/239; 294/87.1; 209/509; 294/185

(57) ABSTRACT

A method of processing IC units comprising the steps of: dicing said IC units from a substrate; delivering said IC units to a idle block; inspecting a face of said units as exposed during the dicing step using an inspection device whilst said units are on said idle block, then; engaging said units with a picker assembly; passing said units over a second inspection device to inspect an opposed face of said units.

### FIELD OF THE INVENTION

The invention relates to the processing of substrates of integrated circuits and their subsequent singulation into individual IC units. In particular, the invention relates to the manipulation of the IC units for subsequent processing.

### BACKGROUND

In the processing of integrated circuit units (IC units), said units are manufactured as a substrate of many such units. The substrate is subsequently singulated into individual IC units, which are delivered to a sorting station for sorting into reject, good or re-work categories.

The sorting stage involves inspecting the units to ensure the singulation stage didn't damage the units, or leave detritus on said units affecting quality or damaging equipment.

To mitigate such detritus, the units are washed and dried prior to inspection. One such method is to deliver the units to a drying plate, and then subjecting the units to a flow of hot air derived from a heater. The heater heats an airflow passing over the heating units, with the heating units maintained at a certain temperature to ensure the air flow is maintained at the correct temperature. When the air flow is stopped, either because of a temporary halt to the system or other such reason, the heaters rapidly increase in temperature due to the lack of convective cooling. This rapid escalation can lead to burning out of the heaters, and so shortening the life of the heating unit to 1 to 2 months.

After washing, the units are then passed to a flipper for inverting the units so as to inspect an underside of the said units, before delivering the units to the sorting area for further inspection.

The delivery of the units to the next inspection station is performed by a picker assembly having a line array or rectangular array of pickers, each of which is arranged to engage a single IC unit. It has been found that, on occasion a picker will be jammed in an extended position rather than the normal retraction after engaging or disengaging a picker. If the picker assembly moves about the processing device with a picker extended, significant damage will result to the picker and possibly other equipment as the rapidly moving picker assembly moves to the next station.

One type of inspection to which the picker assembly delivers the IC units involves the placing the UIC unit within a conventional inspection space, whereby an array of lights illuminate the IC unit for inspection by a camera. This involves extending the picker into the inspection space, and stopping just short of contact, so as to avoid damage. Being a cantilever, there is inherent vibration as the picker stops movement, which leads to a delay of up to 0.2 s whilst the vibration subsides.

On inspection, the light array emits a high intensity light to ensure no shadows obscure parts of the IC unit from detection. The downside is that this high intensity light, occurring frequently at high speed can lead to a irritating, and possibly retina damaging event, even from a distance from the processing device.

### SUMMARY OF INVENTION

In a first aspect the invention provides a method of processing IC units comprising the steps of: dicing said IC units from a substrate; delivering said IC units to a idle block; inspecting a face of said units as exposed during the dicing step using an inspection device whilst said units are on said idle block, then; engaging said units with a picker assembly; passing said units over a second inspection device to inspect an opposed face of said units.

Accordingly, by removing the “flipping” step, the processing rate for the processing device is increased, leading to an improved output, without affecting the quality of the product.

In a second aspect the invention provides a system for processing IC units comprising: a dicing station for singulating said IC units from a substrate; a idle block for receiving said IC units in an orientation as singulated; an inspection device arranged to inspect said units on said idle block; a picker assembly for engaging and delivering said units to a second inspection station; and a second inspection device for inspecting an opposed face of said units.

In a third aspect the invention provides a drying plate assembly for drying IC units comprising a drying plate for receiving said IC units on a plate surface, said drying plate in heat transfer communication with a heating source for increasing the temperature of said plate; an air vent for directing a flow of air onto said surface so as to dry said IC units; wherein said drying plate includes conduits for receiving a flow of air from an air source, said conduits in communication with the air vent, said plate arranged to impart heat to said air whilst in the conduits so as to provide air of elevated temperature to said air vent.

Thus, by eliminating the heating unit, and using the existing heating system of the drying plate assembly, not only is a piece of capital equipment (the heating unit) avoided, but ongoing maintenance costs may be reduced, by not having to replace burnt out units.

In a fourth aspect the invention provides a picker assembly for engaging a plurality of IC units, the assembly comprising: a housing to which are mounted an array of pickers; each picker arranged to move in reciprocal motion from a retracted position to an extended position; a light source and corresponding target arranged adjacent to said array of pickers such that a beam from said light source to said target is directed perpendicular to a direction of said reciprocal motion; wherein each of said pickers includes a corresponding lug mounted thereto, said lug arranged such that the corresponding picker in a retracted position places the lug distal from said beam and the corresponding picker in an extended position places said lug in a position to obstruct the beam.

By providing an optical limit switch, in the form of a light source that is obstructed when a picker remains extended, damage to the picker, the picker assembly and other components may be avoided.

In a fifth aspect the invention provides a unit picker for engaging an IC unit, comprising: a picker head having a recess in communication with a vacuum source for engaging said IC unit at an opening of said recess; said picker head having a contact surface peripherally located about said recess; said contact surface sized in a direction orthogonal to direction of reciprocal motion of the picker, so as to contact a peripheral edge of an inspection orifice; wherein the picker head is in contact with said peripheral edge on insertion of the IC unit into the orifice.

By providing a picker head arranged to allow the picker to make contact, the picker can dampen vibration, reducing the delay time normally associated with a free standing picker.

In a sixth aspect the invention provides an inspection chamber comprising an inspection station arranged to inspect an IC unit, said inspection station including a light array for illuminating the IC unit; a cover having a viewing portion so as to separate the inspection station from an operator; wherein said light array includes a first polarizing film of a first orientation and the viewing portion of the cover having a second polarizing film, said polarizing films arranged so as to reduce the intensity of light received by the operator from the light array.

Thus by providing a polarizing filter the operator is protected from the high intensity inspection light. However, by having the polarizing films in two parts, the intended purpose of providing the inspection light is not diminished as the first polarizing film provides very little effect on the light intensity.

In a seventh aspect the invention provides a sorting system comprising a plurality of net blocks, each net block arranged to receive a plurality of singulated IC units; wherein said net blocks operate independently to cumulatively transport said plurality of singulated IC units to a sorting section.

In a eighth aspect the invention provides a dicing saw array for the singulation of IC units from a substrate, the array comprising: a plurality of pairs of dicing saws with each dicing saw within each pair spaced from the corresponding dicing saw; the spacing of one pair of dicing saws being different from the spacing of the other pairs of dicing saws; wherein the pairs of dicing saws are selectively exchangeable so as to switch between the pairs of dicing saws based upon a required spacing.

In a ninth aspect the invention provides a dicing saw array for the singulation of IC units from a substrate, the array comprising; at least one pair of dicing saws, said dicing saws mounted to a rail in moveable engagement; wherein the spacing of said dicing saws is adjustable through movement along said rail.

### BRIEF DESCRIPTION OF DRAWINGS

It will be convenient to further describe the present invention with respect to the accompanying drawings that illustrate possible arrangements of the invention. Other arrangements of the invention are possible and consequently, the particularity of the accompanying drawings is not to be understood as superseding the generality of the preceding description of the invention.

FIG. 1 is a plan view of a sawing and sorting system according to one embodiment of the present invention;

FIG. 2 is a plan view of sawing and sorting system according to one embodiment of the present invention;

FIGS. 3A, 3B and 3C are various views of a drying plate according to one embodiment of the present invention;

FIGS. 4A, 4B, 4C and 4D are various views of a picker assembly according to a further embodiment of the present invention;

FIGS. 5A and 5B are various views of an IC Unit;

FIGS. 6A to 6D are various views of a picker head according to one embodiment of the present invention;

FIG. 7B is an elevation view of an inspection station according to the prior art;

FIG. 7A and 7C are elevation views of an inspection station according to a further embodiment of the present invention;

FIG. 8 is an elevation view of an inspection station according to a further embodiment of the present invention;

FIGS. 9A and 9B are elevation views of an inspection station according to a further embodiment of the present invention;

FIGS. 10A and 10B are elevation views of an inspection station according to a further embodiment of the present invention;

FIG. 11 is an isometric view of an inspection device according to a further embodiment of the present invention;

FIGS. 12A to 12C are various views of an array of dicing saws according to the prior art;

FIGS. 13A to 13C are various views of an array of dicing saws according to a further embodiment of the present invention;

FIGS. 14A to 14C are various views of an array of dicing saws according to a further embodiment of the present invention;

### DETAILED DESCRIPTION

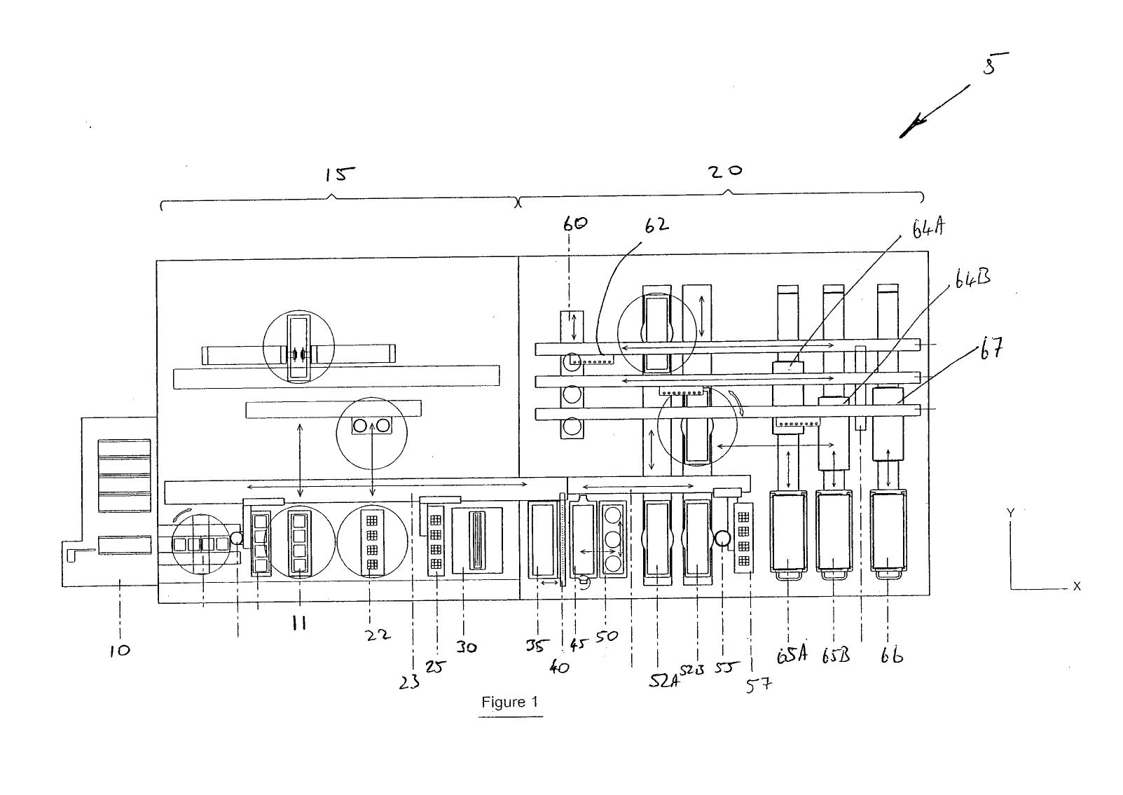

FIG. 1 shows a sawing and sorting system 5 according to one embodiment of the present invention. The system 5 comprises a sawing section 15 and a sorting section 20, each having various stages in order to process a substrate of IC units from an input station 10 to output trays 65A, 65B and 66.

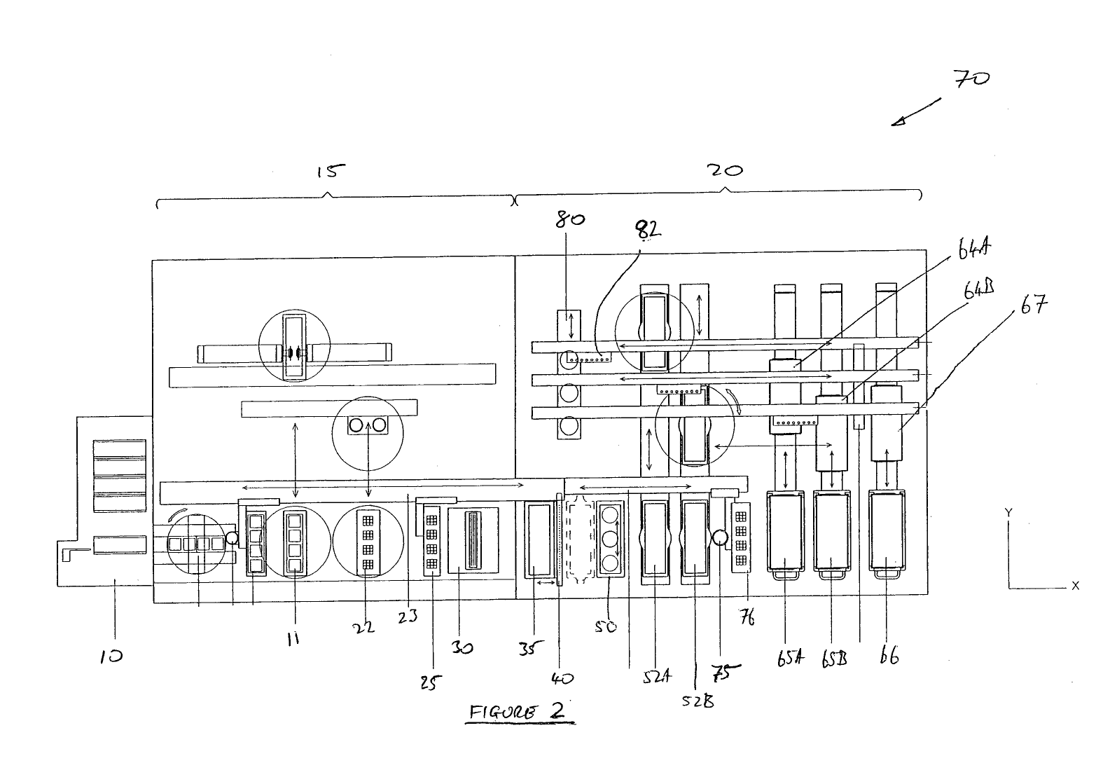

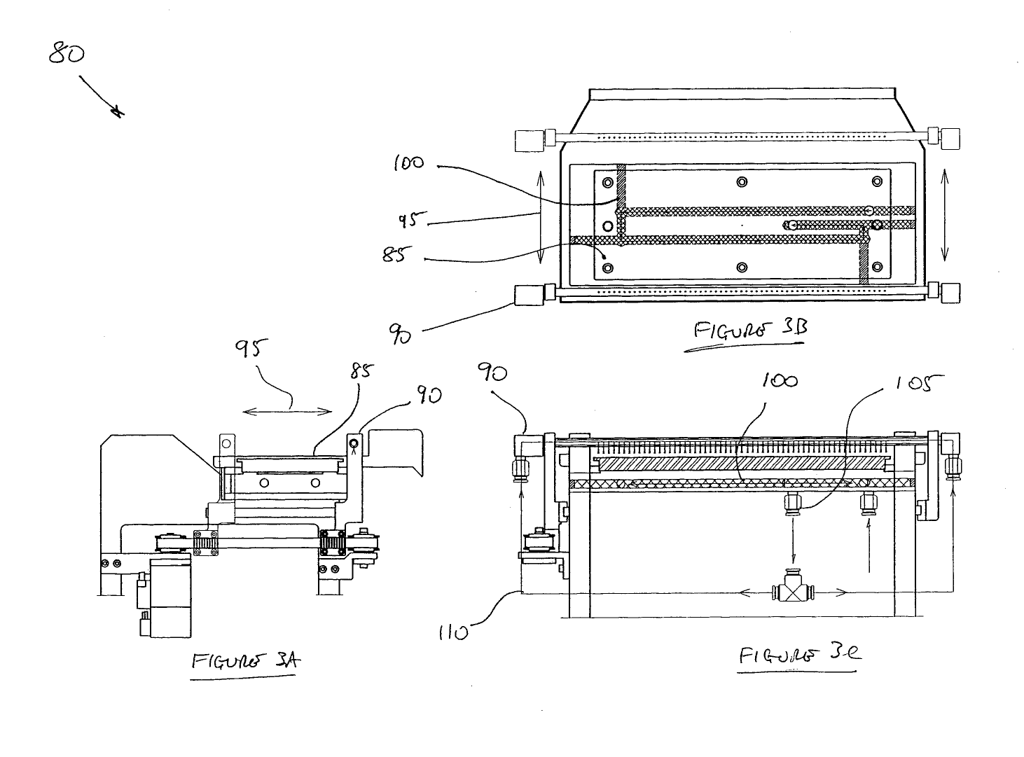

The sawing section 15 involves taking a substrate 11 and singulating the IC units so as to place them on a tray 22 for transport using a picker 25 to a cleaning station 30. The singulated IC units are washed before being deposited upon a dry plate 35 so as to be subjected to hot air from a hot air vent 40. For the present embodiment shown in FIGS. 1 and 2, the drying table and hot air vent may be a conventional drying station or alternatively, may be a drying station according to one embodiment of the present invention as shown in FIGS. 3A to 3C.

The washed and dried units are then deposited upon a flipper 45 and flipped so as to be inspected by a vision device 55 on a common rail before being placed onto idle blocks 50 by the picker 57. The idle blocks 50 then deliver the IC units to sorting section 20 where upon pickers 62 engaged individual units to inspect from an underside of the unit. A control system determines whether the units are good and so as to be deposited in trays 64A, 64B or in the re-worked tray 67. If however the units are to be rejected than they are placed in a bin.

The system further includes good tray off loaders 65A, 65B and so providing for a faster offloading of the good units. As one off loader 65A is being filled through a corresponding tray 64A, the other tray 65B having reached its capacity can be offloaded. The empty offloaded tray 65B is than replaced ready to receive units from the corresponding tray 64B where upon the other good tray off loader 65A can be removed and the packaged IC units offloaded for transport.

Thus, the system 5 as shown in FIGS. 1 and 2 by providing dual net blocks 52A, 52B and two good tray off loaders 65A, 65B can increased the rate of delivery of IC units to the sorting section 20 and removal of the good IC units from the sorting section 20 for packaging. The result is a higher through rate of IC units through the sorting section 20 thus increasing the rate of processing of the units.

The sawing and sorting system 70 shown in FIG. 2 is identical to that of the system 5 shown in FIG. 1 with the exception of the removal of the flipper station 45. This has the consequence of the inspection station 75 viewing the face of the IC units exposed during dicing whereas for the embodiment of FIG. 1, this face was inspected by station 60 as a result of the flipping process.

FIG. 2 shows an alternative system 70 to that shown in FIG. 1, according to a further embodiment whereby the flipping station is removed. Accordingly, the inspection is undertaken on the top surface by vision system 75 and the opposed surface inspected through inspection 80. Apart from the benefit of removing a processing step, the ability to sort and deliver the units in a particular orientation is provided.

One alternative arrangement of the cleaning table 35 of FIGS. 1 and 2 is shown in FIGS. 3A to 3C, as a drying table 80. Prior to delivery to the table 80, the IC units are washed, and then placed on the table surface 85. As with the prior art the table surface 85 is heated to facilitate the drying process. Further, hot air is delivered through moving 95 air vents 90 over the units in a sweeping motion, so as to further accelerate drying.

The hot air is normally delivered from a hot air supply, comprising a heater through which air passes, so to impart heat convectively. On completion of the drying process, or during a temporary halt in processing, the air no longer passes through the heater, and so heat loss from the heater through convection is stopped. The heater will consequently increase in temperature until the unit is turned off. Thus, the heater will go through a cycle of overheating and re-heating subject to the delivery of air through the heater in order to dissipate heat. This cycle of heat/no heat substantially shortens the life of the heating unit, and more so if the heater is not in fact turned off, allowing the heater to burn out. A replacement period of 1 to 2 months may be experienced, at a significant cost and loss of productivity.

For the present invention, the drying table 80 includes conduits 100 within the table surface 85. The heating unit that applies heat to the heating surface 85, therefore also elevates the temperature of the air in the conduit. Because the heating unit for the plate does not rely on a significant convective heat loss, if the air is turned off, there is no diverging heat output that would affect the life of the heater. As the drying table is massive, the addition of the air in the air conduit does not represent a significant loss of heat, and so no additional heat is necessary to operate the drying and air heating function. Of course, an additional heat source may be used if so desired. The air is then delivered 105 to the moving vents 90 for application to the units on the table surface 85 in the normal manner.

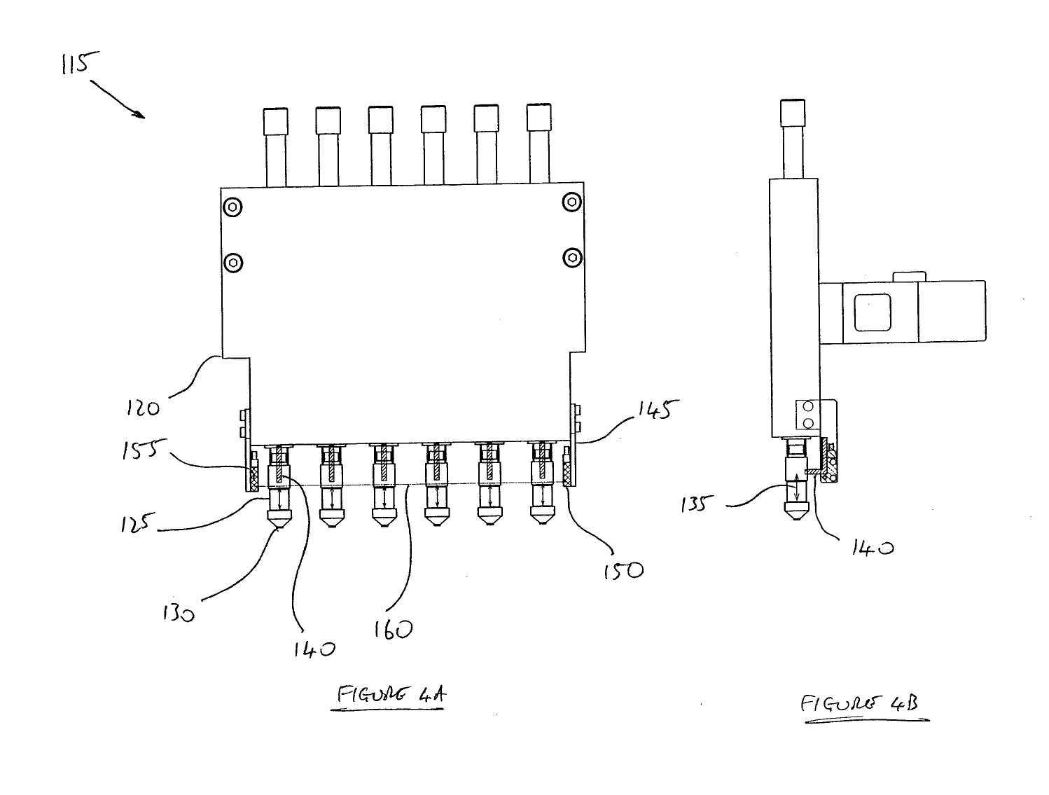

FIGS. 4A and 4B show a picker safety system used for protecting an extended picker from damage. The picker assembly 115 is similar to that of the prior art with the exception of a bracket 145 mounted to the picker housing 120 and a plurality of lugs 140 mounted to each of the pickers 125. The bracket 145 includes a laser 150, or other optical device, directed at right angles to the direction of the pickers aligning with a target 155 at an opposed end of the pickers housing 120. The lugs 140 mounted on each of the pickers 125 are placed such that when each picker 125 is retracted 135 the lugs 140 lie above the beam 160 generated by the laser 150, leaving the beam unobstructed. When the pickers 125 are extended 165, as shown in FIG. 4C and 4D, the lugs of the extended pickers 125 block the beam 160. The system may be connected to a simple circuit which indicates the extended picker through a light, sound or other operator directed signal. Alternatively, the system may in communication with a control system such that on obstructing the beam, the control system suspends operation of the machine, or suspends operation of the picker assembly 115 only, so as to protect the extended picker.

Accordingly, the use of the picker safety system according this embodiment prevents the picker assembly from incurring significant and costly damage due to stuck pickers.

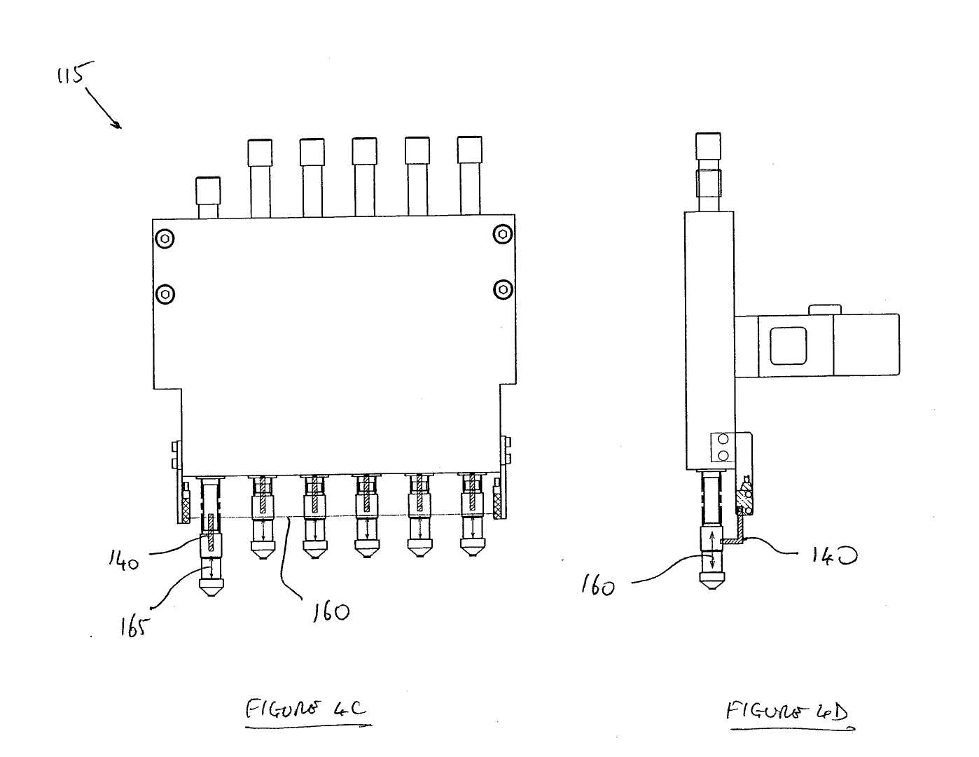

FIGS. 5A and 5B show an integrated circuit unit 165. In particular, it identifies the direction 175 from which a surface inspection may be undertaken, so as to determine any material stuck to the surface of the unit 165, so as a burr or an electrode 170 which may be out of place.

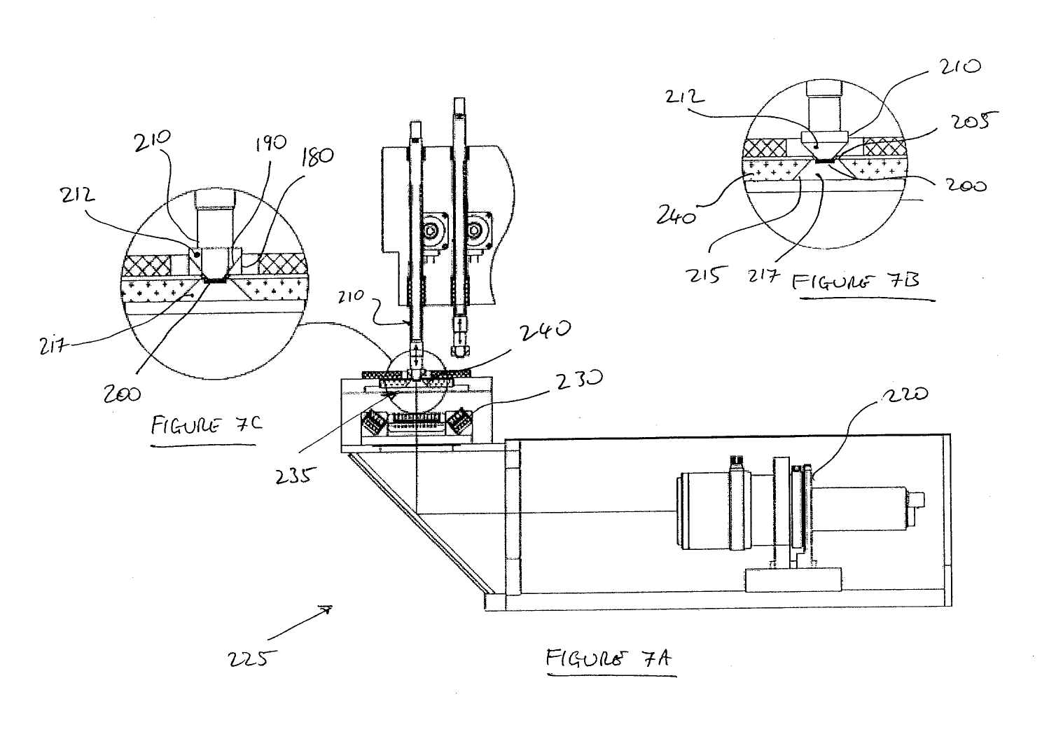

In undertaking such an inspection, a device 225 similar to that shown in FIG. 7A may be used. Here a camera 220 receives vision from an inspection station 235. Here, a picker 210 having an IC unit 200 directed the unit 200 into a recess. The recess includes a mirror face 215, located on a mirror block 240, which reflects light from a light array 230 and directs the illuminated image to the camera 220. In this way, a view across the face of the unit, similar to that shown in FIG. 5B can be achieved.

In projecting the unit 200 into the inspection space 217, the picker is arranged to avoid contact with any edges of parts of the inspection station shown in FIG. 7B. Movement of the picker inevitably causes vibration to the system affecting the high precision inspection and so a delay of up to 0.2 seconds is required for each unit in order to allow the vibration to dissipate.

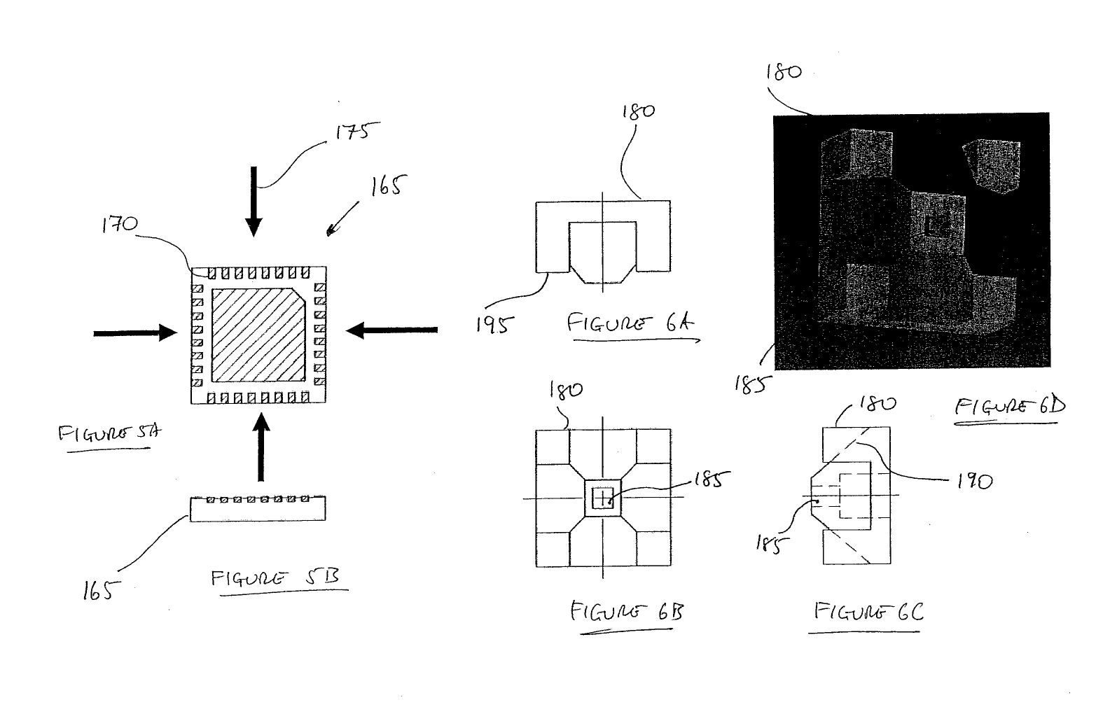

In the embodiment shown in FIGS. 6A to 6D, an alternative picker head 180 is provided for insertion into the inspection station such that the picker head 180 contacts the peripheral edge of the orifice into which the inspection space is provided. Thus, rather than hold the picker above the inspection space, the new picker head 180 is arranged to contact the table located around the orifice and so damping any vibration. The picker head may be made of a material suited for dampening vibration.

Alternatively, the picker head may have a film or tab of material on the surface intended to make contact with the inspection station table, and so avoid any damage either to the table or to the picker head.

Thus, rather than wait for the dissipation of vibration, the dampening from contact with the support block allows inspection to occur almost instantaneously or at least having a significantly shortened delay of, for instance, 0.05 seconds. Thus, use of the support block within the inspection zone and permitting the picker to contact the said support block provides substantial advantage in the rate of inspection.

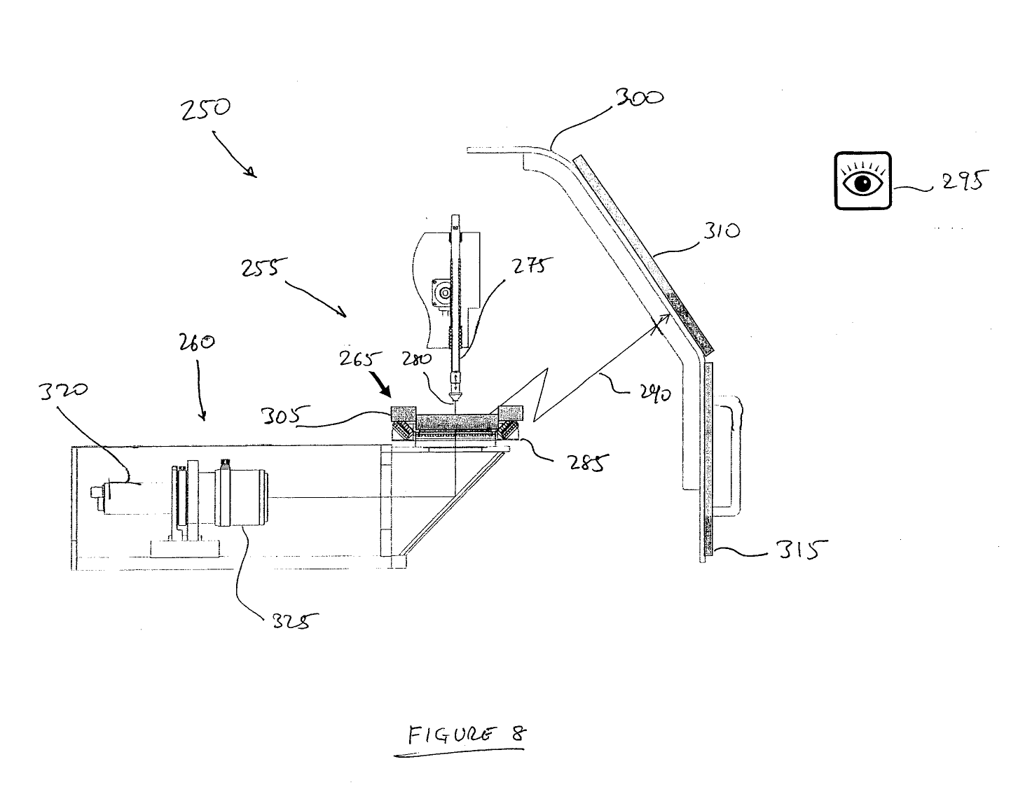

FIG. 8 shows an inspection chamber 250 for a sorting system. The inspection chamber 250 includes an inspection station 255 similar to that shown in FIG. 7A, having a light array 285 to direct light on an image captured by a camera 320 within a vision station 260.

The chamber includes a transparent cover 300, having a viewing portion, through which an operator 295 can monitor the inspection and other process. Alternatively, the operator may view the process through the window of an opaque cover.

A picker 275 directs an engaged unit 280 towards the inspection station, whereby the light array 285 illuminates the unit 280. The difficulty arises when the intensity of light from the array can affect the operator. After repeated exposure to extreme light, this may prove a hazard to the operator, or at least be an irritant source.

In the present embodiment, to overcome the light intensity, the light array 285 includes a first polarizing film 305 of known orientation. Further, to the transparent cover 300, or window in the case of an opaque cover, a second polarizing film 310, and possibly a through 315 are affixed. The orientation of the first and second polarizing films 305, 310 are such so as to reduce the intensity of the light though filtering the wave form of light passing through said films. Subject to the expected position of the operator, the two films may be oriented so as to minimize the effect of the light on the operator for his normal operating position. The relative orientation of the first and a subsequent film arranged on a different portion of the viewing portion may similarly be arranged, subject to the line of sight of the operator, or other workers within the factory environment.

Accordingly, the invention provides for polarizing films, at selected relative orientation. Importantly, to avoid interference of the illuminated light for the inspection, the films are separated, and so whilst the inspection light 290 passes through the first film, the effect is negligible until it passes through the second film, for which the operator will benefit from the polarized light.

As the light array 285 is a square array, light directed from the side of the light array will require a different orientation to that of the front and back arrays. Accordingly, in an alternative arrangement, the film 305 on the side arrays may receive a third and fourth film having different orientations to the first film on the back and front arrays. For instance, the front array may have a first film of orientation of 90° with the side arrays having a third and fourth film of orientations ±45°. This will be matched to an orientation of the second film 310 on the cover 300 of 0°. Thus, the greatest polarization will occur for the more intense front array, with a compromised reduction from the side arrays.

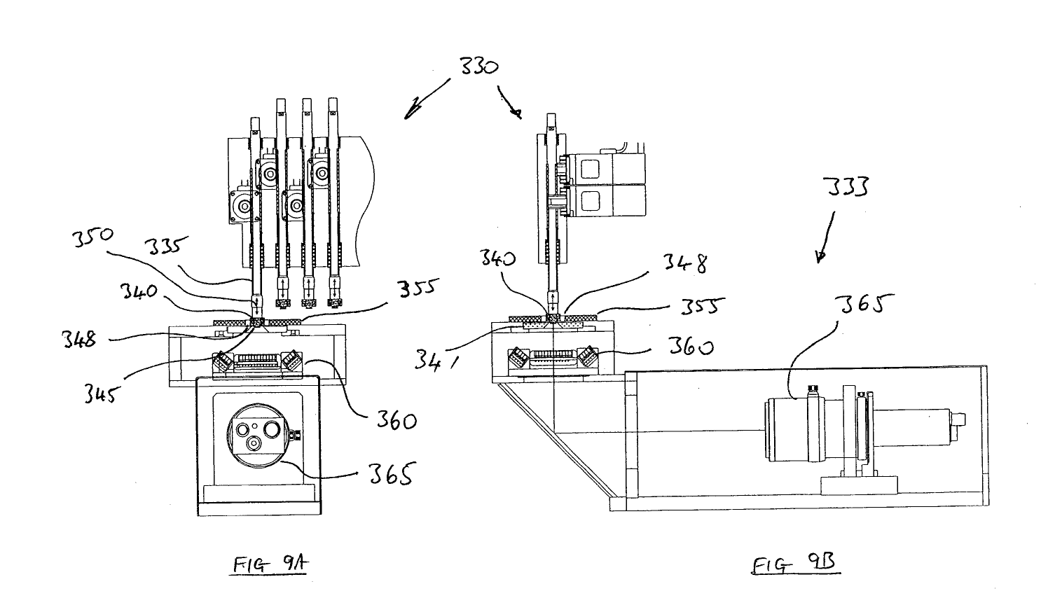

FIGS. 9A and 9B show a similar inspection device 333 to that shown in FIGS. 7A to 7C. Here, a picker 335 moves 350 in a reciprocal motion to insert an IC unit 345 into an orifice 348 through resting the picker head 340 on the table ready for inspection. A camera 365 receives vision of the IC unit 345 through the light array 360 directing a light onto the IC unit 345 and directed through the mirror block 341.

Each picker within the picker assembly 330 then sequentially places an IC unit within the inspection zone so as to inspect all the units handled by the picker assembly 330.

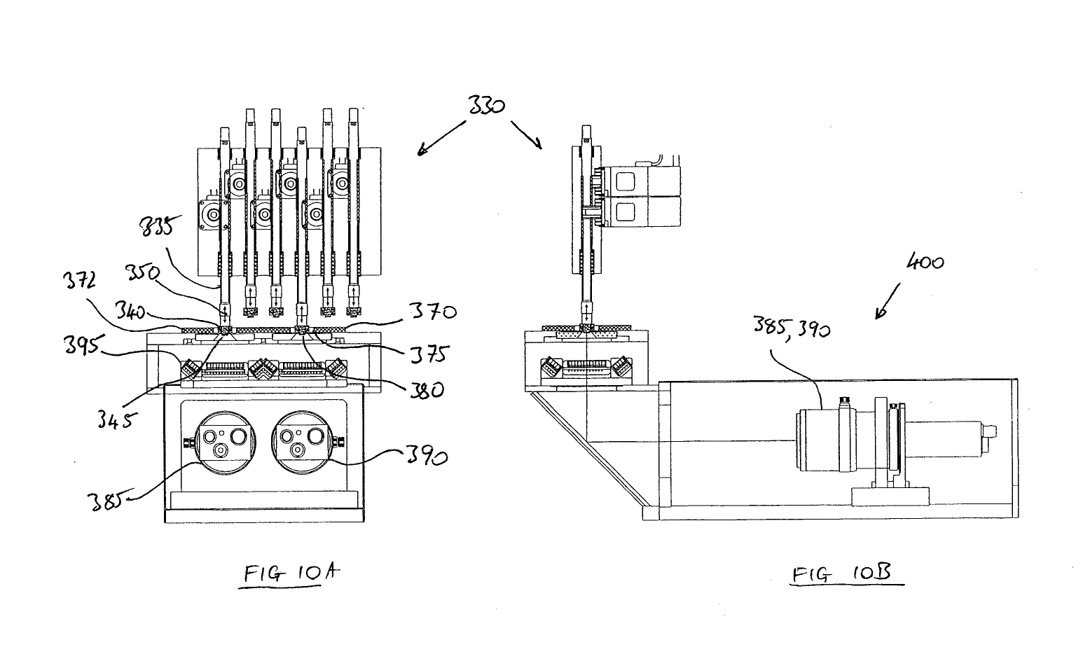

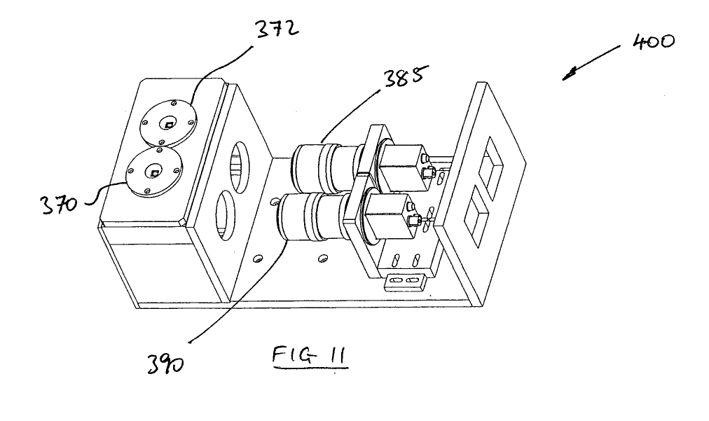

FIGS. 10A and 10B show an alternative embodiment whereby the picker assembly 330 instead of sequentially inserting the IC units into a single inspection station, the inspection device 400 includes two inspection zones defined by tables 370, 372. The light array 360 is replaced by a dual light array 395 so as to direct light to two IC units 345, 380 projecting through into the inspection zone through the dual mirror blocks.

Accordingly, the device 400 includes two cameras 385, 390 for receiving vision of the two IC units 345, 380 either simultaneously, or in very close succession. This results in doubling the rate of inspection as compared to the system of FIGS. 9A and 9B.

In the singulation of a substrate into individual IC units, prior art systems involve a chuck table supporting the substrate which moves the substrate relative to a dicing saw. By running the full length of the substrate against the dicing saw, longitudinal cuts into the substrate may be achieved and so result in the singulation of the substrate. To increase the rate of singulation, pairs of dicing saws have been used together with twin chuck tables with each member of the pair corresponding to a dedicated dicing saw. Operation of the twin chuck tables is similar to that of the single dicing saw with the chuck table moving relative to the corresponding saw.

Other systems involve adding twin blades to the dicing saws so as to execute two cuts at a time to the substrate so as to further increase the units per hour (“UPH”) of the system. However, in all systems, the fixed dicing saws are positioned so as to be consistent with the size of the IC units and so having the spacing of the twin saws being fixed for a particular package size.

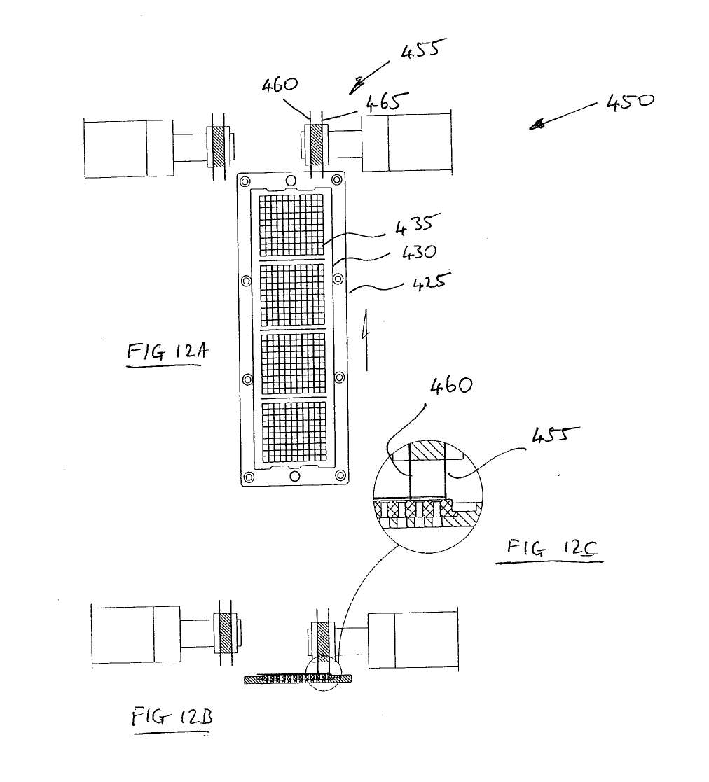

FIGS. 12A to 12C shows such a prior art system whereby a pair of dicing saws 450 having a twin blade head 455 are in fixed relative position to each other. The chuck table 425 moves relative to the dicing saw so as to singulate the units 435 from the substrate. The spacing of blades 460, 465 of the twin blade head 455 therefore correspond to multiples of the width of individual IC units. Whilst being able to effect two cuts per pass of the chuck table 425, should a different substrate be entered into the system, not only will the relative position of the dicing saws need adjusting but further the position of the individual blades 460, 465 will also need adjusting to correspond to the different widths of the IC units.

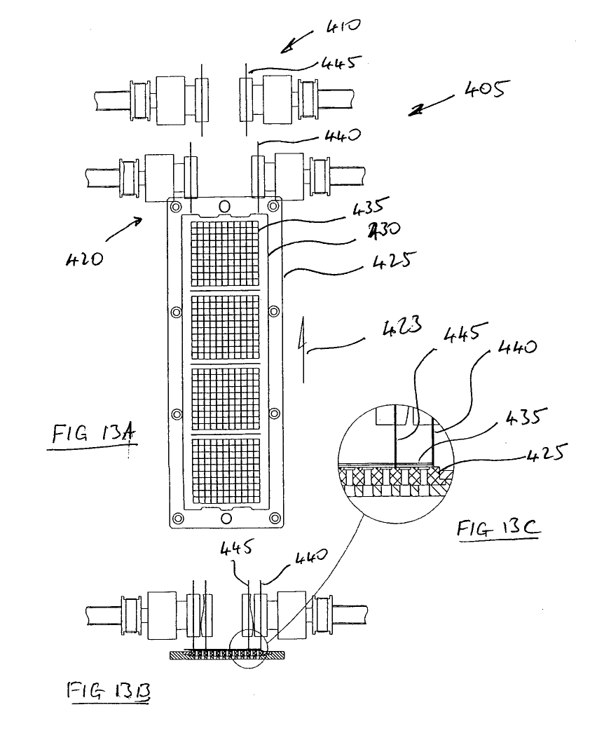

FIGS. 13A to 13C show an alternative arrangement according to the present invention. Here, an array of dicing saws 405 comprises two pairs 410, 420 of dicing saws having different relative spacing.

In this arrangement the chuck table 425 is moved 423 relative to the dicing saw array 405. The substrate 430 is subject to four blades corresponding to the four dicing saws of the array 405. This yields certain advantages. Firstly, by adjusting the pitch, that is the spacing between the two dicing saws, of the first pair 410 the spacing between blades 440, 445 can be adjusted to accommodate IC units of a different size as can be seen in FIG. 13C. Further, by adjusting the position of all the dicing saws within the two pairs 410, 420, substrates of different size can also be accommodated within the same arrangement. Adjustment by a square thread engagement of the saws, which may be in communication with a stepper motor, may automatically adjust the saws to the desired pitch in order to accommodate a known substrate in IC unit size. The required spacing for the desired substrate in IC units may be manually adjusted by an operator or may be automatically achieved by a control system receiving data from an upstream inspection which identifies the substrate and IC unit spacing and automatically adjusting the pitch of the saws corresponding to the identified substrate in IC unit.

A further advantage of the system of FIGS. 13A to 13C over the twin blade dicing saw is the ability to have a very fine spacing between corresponding blades. FIG. 12A shows the double blade pair 455 having the two blades 460, 465 mounted to a single axle of the dicing saw. As the two blades are adjacent, it follows they will cut at the same time and so subjecting the substrate to a double cut simultaneously. The separation of the two blades 460 and 465 therefore yields an interference between the cuts particularly if the spacing between the blades is very small. Compare this to the arrangement in FIGS. 13A to 13C. Here, because the blades are staggered from each other, adjacent blades 440, 445 in fact do not cut simultaneously and so the problem of simultaneous cutting of the prior art double head dicing saw is avoided. It follows further that the size of an IC unit that may be cut according to the embodiment of FIG. 13A may be much smaller than that of the double head arrangement of the prior art.

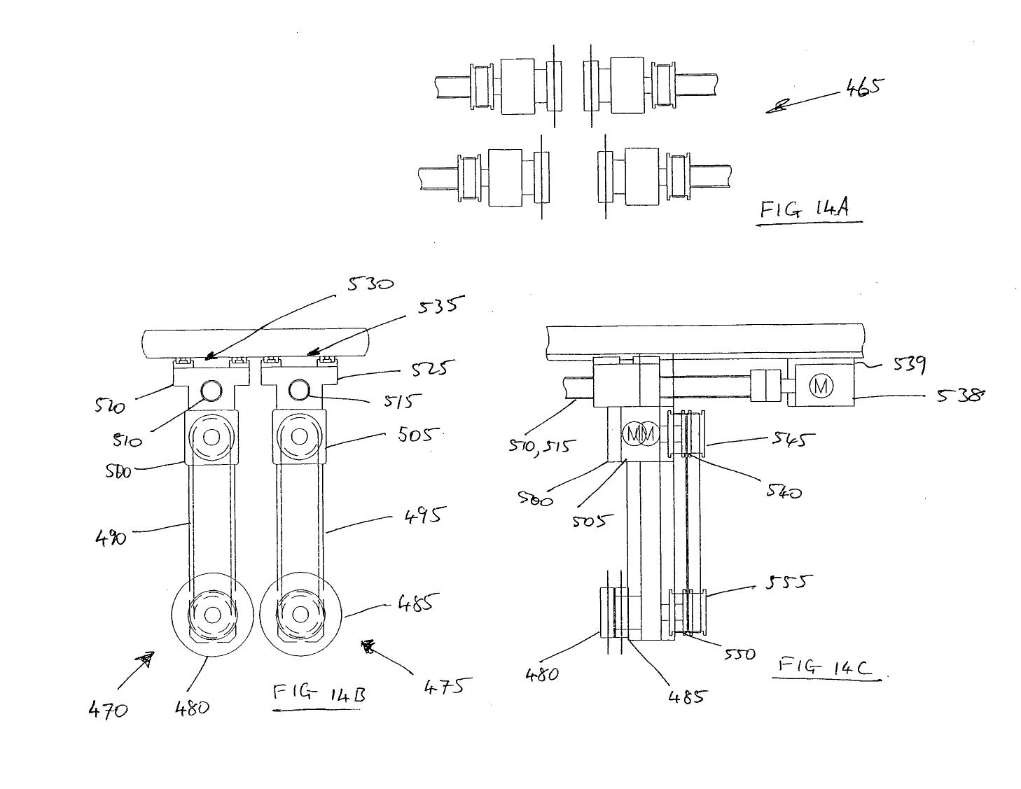

FIGS. 14A to 14C show another embodiment according to the present invention. Here, a similar dicing saw array 465 has the dicing saws mounted to corresponding threading rods 510, 515, each of which correspond to a motor 538, 539. The dicing saws 480, 485 each have pulleys 550, 555 which are driven by corresponding motors 500, 505 through engaged drive wheels 540, 545. The normal elongate dicing saws are replaced by assemblies driven by corresponding motors 500, 505 with the pitch of the dicing saws controlled by movement along the threaded rods 510, 515. Thus, by driving the dicing saws along the threaded rods the position of the dicing saws can be determined very accurately so as to provide both the correct position for the respective substrate as well as very fine movement for the singulation of IC units within the substrate.

1. A method of processing IC units comprising the steps of:
dicing said IC units from a substrate;
delivering said IC units to a idle block;
inspecting a face of said units as exposed during the dicing step using an inspection device whilst said units are on said idle block, then;
engaging said units with a picker assembly;
passing said units over a second inspection device to inspect an opposed face of said units.

2. A system for processing IC units comprising:
a dicing station for singulating said IC units from a substrate;
a idle block for receiving said IC units in an orientation as singulated;
an inspection device arranged to inspect said units on said idle block;
a picker assembly for engaging and delivering said units to a second inspection station;
and a second inspection device for inspecting an opposed face of said units.

3. A drying plate assembly for drying IC units comprising
a drying plate for receiving said IC units on a plate surface, said drying plate in heat transfer communication with a heating source for increasing the temperature of said plate;
an air vent for directing a flow of air onto said surface so as to dry said IC units;
wherein said drying plate includes conduits for receiving a flow of air from an air source, said conduits in communication with the air vent, said plate arranged to impart heat to said air whilst in the conduits so as to provide air of elevated temperature to said air vent.

4. The drying plate assembly according to claim 3, wherein said conduits selected to be of sufficient length to permit the air to reach a desired temperature.

5. The drying plate assembly according to claim 3, wherein said air vents arranged to move across the plate to ensure the air is directed across the plate surface.

6. A picker assembly for engaging a plurality of IC units, the assembly comprising:
a housing to which are mounted an array of pickers;
each picker arranged to move in reciprocal motion from a retracted position to an extended position;
a light source and corresponding target arranged adjacent to said array of pickers such that a beam from said light source to said target is directed perpendicular to a direction of said reciprocal motion;
wherein each of said pickers includes a corresponding lug mounted thereto, said lug arranged such that the corresponding picker in a retracted position places the lug distal from said beam and the corresponding picker in an extended position places said lug in a position to obstruct the beam.

7. The picker assembly according to claim 6, wherein the array of pickers is arranged in a line.

8. The picker assembly according to claim 6, wherein the array of pickers is a rectangular array, with a corresponding light source and target associated with each line of pickers within said array.

9. The picker assembly according to claim 6, wherein said light source and/or target are mounted to said housing.

10. The picker assembly according to claim 6, wherein the light source is a laser.

11. A unit picker for engaging an IC unit, comprising
a picker head having a recess in communication with a vacuum source for engaging said IC unit at an opening of said recess;
said picker head having a contact surface peripherally located about said recess;
said contact surface sized in a direction orthogonal to direction of reciprocal motion of the picker, so as to contact a peripheral edge of an inspection orifice;
wherein the picker head is in contact with said peripheral edge on insertion of the IC unit into the orifice.

12. The inspection station according to claim 11, wherein said support block includes inclined faces on a receiving void

13. An inspection chamber comprising
an inspection station arranged to inspect an IC unit, said inspection station including a light array for illuminating the IC unit;
a cover having a viewing portion so as to separate the inspection station from an operator;
wherein said light array includes a first polarizing film of a first orientation and the viewing portion of the cover having a second polarizing film, said polarizing films arranged so as to reduce the intensity of light received by the operator from the light array.

14. The inspection chamber according to claim 13, wherein said light array comprising four light sub-arrays arranged in a rectangular formation about an inspection space into which the IC unit is delivered.

15. The inspection chamber according to claim 13, wherein the first polarizing film is applied to a sub-array aligned to direct light towards said viewing portion.

16. The inspection chamber according to claim 13, further including a third and fourth film placed on opposed side sub-arrays, each having an orientation to reduce light intensity received by the operator from the sub-arrays.

17. A sorting system comprising
a plurality of net blocks, each net block arranged to receive a plurality of singulated IC units;
wherein said net blocks operate independently to cumulatively transport said plurality of singulated IC units to a sorting section.

18. The system according to claim 17 wherein there are two said net blocks.

19. The system according to claim 17 further including a plurality of good tray offloaders, said offloaders arranged to receive inspected singulated IC units from corresponding trays wherein the plurality of net blocks and plurality of good tray offloaders are separated by a plurality of unit pickers for transporting said units from the net blocks to the good tray offloaders via corresponding good unit trays.

20. A dicing saw array for the singulation of IC units from a substrate, the array comprising:
a plurality of pairs of dicing saws with each dicing saw within each pair spaced from the corresponding dicing saw;
the spacing of one pair of dicing saws being different from the spacing of the other pairs of dicing saws;
wherein the pairs of dicing saws are selectively exchangeable so as to switch between the pairs of dicing saws based upon a required spacing.

21. The dicing saw array according to claim 20 wherein the spacing of each pair corresponds to any one or a combination of: substrate size, IC unit size, number of IC units within said substrate.

22. A dicing saw array for the singulation of IC units from a substrate, the array comprising
at least one pair of dicing saws, said dicing saws mounted to a rail in moveable engagement;
wherein the spacing of said dicing saws is adjustable through movement along said rail.

23. The dicing saw array according to claim 22 wherein the rail is a threaded rod and said moveable engagement of the dicing saws is in reverse threaded engagement, the threaded rod arranged such that rotation of the rod results in the simultaneous movement of the dicing saws along the rod in opposed directions.
